(19) United States
(12) Patent Application Publication
(10) Pub. No.: US 2026/0286077 A1
(43) Pub. Date: Sep. 24, 2026

(54) RESIN COMPOSITION, PREPREG, LAMINATE, RESIN FILM, PRINTED WIRING BOARD, AND SEMICONDUCTOR PACKAGE

(71) Applicant: Resonac Corporation, Minato-ku, Tokyo (JP)

(72) Inventors: Haruki ANDO, Minato-ku, Tokyo (JP); Tomohiko KOTAKE, Minato-ku, Tokyo (JP); Hiroki KUZUOKA, Minato-ku, Tokyo (JP); Shinichiro ABE, Minato-ku, Tokyo (JP)

(21) Appl. No.: 19/477,514

(22) PCT Filed: Oct. 23, 2024
(86) PCT No.: PCT/JP2024/037740

§ 371 Date: Oct. 22, 2025

(30) Foreign Application Priority Data
Oct. 26, 2023 (JP) 2023-183841

(51) Int. Cl. C08J 5/24; C08J 5/18; C08L 25/16; C08L 63/00; H10W 70/695

(52) U.S. Cl. CPC C08J 5/244; C08J 5/18; C08L 25/16; C08L 63/00; H10W 70/695; C08J 2325/16; C08J 2363/00; C08J 2425/16; C08J 2463/00; C08L 2203/20

(57) ABSTRACT

Provided are a resin composition containing a thermosetting resin and having a rate of change in a glass transition temperature according to a heat and pressure treatment time as measured under prescribed conditions of −20% to +20%, and a prepreg, a laminate, a resin film, a printed wiring board, and a semiconductor package in each of which the resin composition is used.

### TECHNICAL FIELD

The present embodiment relates to a resin composition, a prepreg, a laminate, a resin film, a printed wiring board, and a semiconductor package.

### BACKGROUND ART

In recent years, miniaturization, weight reduction, and increase in performance of electronic instruments have been advanced and integration of semiconductor devices has been progressing. Under such circumstances, higher reliability than ever is being required for a printed wiring board, a semiconductor package, and the like.

An insulating resin material used in a printed wiring board, a semiconductor package, and the like is required to have heat resistance and mechanical characteristics capable of withstanding the production and use environment thereof. Thus, application of a resin composition in which a thermosetting resin superior in heat resistance and mechanical characteristics is used is examined (see, for example, PTL 1).

### CITATION LIST

### Patent Literature

[PTL 1] JP 2009-1783 A

### SUMMARY OF INVENTION

### Technical Problem

In forming a substrate for printed wiring board and the like using a resin composition containing a thermosetting resin, the resin composition is cured by applying a heat and pressure treatment in which the resin composition is pressurized with heat.

Since reduction in the amount of electricity used has been required for achieving recycling society in recent years, reduction in the time for a heat and pressure treatment of a resin composition (hereinafter also referred to as “heat and pressure treatment time”) is demanded. However, when the heat and pressure treatment time of the resin composition is simply decreased, a problem arises in that adhesion strength to a conductive layer (hereinafter also referred to as “conductor adhesion”) is greatly reduced probably due to insufficient curing of the thermosetting resin. In addition, the heat and pressure treatment time for a resin composition differs depending on the structure of the target semiconductor package, and thus, it is desired to exhibit a stable conductor adhesion even when the heat and pressure treatment time is varied.

In view of the above situation, the present embodiment has an object to provide a resin composition that exhibits a small change in the conductor adhesion even when the heat and pressure treatment time is varied, and a prepreg, a laminate, a resin film, a printed wiring board, and a semiconductor package in each of which the resin composition is used.

### Solution to Problem

As a result of studies for solving the above problem, the present inventors have found that the problem can be solved by the present embodiments [1] to [9].

[1] A resin composition containing a thermosetting resin,
the resin composition having a rate of change in a glass transition temperature according to a heat and pressure treatment time as measured under the following conditions of −20% to +20%.

### (Measurement Method of Rate of Change in Glass Transition Temperature According to Heat and Pressure Treatment Time)

Seven sheets of a prepreg having a thickness of 0.1 mm and containing the resin composition and a glass cloth (type of glass: T-glass, basis weight: 114 g/m², thickness of glass cloth: 0.098 mm) are stacked and subjected to a heat and pressure treatment under conditions of a temperature of 240° C. and a pressure of 3.0 MPa for 100 minutes or 40 minutes to obtain a laminate (100) produced with a heat and pressure treatment time of 100 minutes and a laminate (40) produced with a heat and pressure treatment time of 40 minutes.

The laminate (40) and the laminate (100) obtained are each cut into a size in a surface direction of 4 mm×30 mm and dried at 105° C. for 1 hour to produce a specimen. The specimen is used as a measurement object and is subjected to a dynamic viscoelasticity measurement using a dynamic viscoelasticity measuring device under conditions of a temperature rising rate of 5° C./minute, a frequency of 10 Hz, and a measuring temperature range of 40 to 400° C., and in a temperature-loss tangent (tan δ) curve obtained, a temperature at which tan δ is a maximum value is read as a glass transition temperature (Tg).

From a glass transition temperature Tg(100) of the laminate (100) and a glass transition temperature Tg(40) of the laminate (40), the rate of change in a glass transition temperature according to a heat and pressure treatment time is calculated by the following formula (1).

$$Rate of change in glass transition temperature according to heat and pressure treatment time ( \% ) = [ Tg ( 100 ) - Tg ( 40 ) ] \times 100 / Tg ( 100 ) \qquad ( 1 )$$

[2] The resin composition according to the above [1], in which the glass transition temperature Tg(40) is 200 to 400° C.

[3] A prepreg containing the resin composition according to the above [1] or [2] or a semi-cured product of the resin composition.

[4] A laminate including a cured product of the resin composition according to any one of the above [1] to [3] and a metal foil.

[5] A resin film containing the resin composition according to any one of the above [1] to [3] or a semi-cured product of the resin composition.

[6] A printed wiring board including a cured product of the resin composition according to any one of the above [1] to [3].

[7] A semiconductor package including the printed wiring board according to the above [6] and a semiconductor element.

[8] A semiconductor package including a semiconductor element and a cured product of the resin composition according to any one of the above [1] to [3], the cured product of the resin composition sealing the semiconductor element.

[9] A prepreg containing a resin composition and a fiber base material, the resin composition containing a thermosetting resin, the prepreg having a rate of change in a glass transition temperature according to a heat and pressure treatment time as measured under the following conditions of −20% to +20%.

### (Measurement Method of Rate of Change in Glass Transition Temperature According to Heat and Pressure Treatment Time)

Two or more sheets of the prepreg are stacked and subjected to a heat and pressure treatment under conditions of a temperature of 240° C. and a pressure of 3.0 MPa for 100 minutes or 40 minutes to obtain a laminate (100′) produced with a heat and pressure treatment time of 100 minutes and a laminate (40′) produced with a heat and pressure treatment time of 40 minutes.

The laminate (40′) and the laminate (100′) obtained are each cut into a size in a surface direction of 4 mm×30 mm and dried at 105° C. for 1 hour to produce a specimen. The specimen is used as a measurement object and is subjected to a dynamic viscoelasticity measurement using a dynamic viscoelasticity measuring device under conditions of a temperature rising rate of 5° C./minute, a frequency of 10 Hz, and a measuring temperature range of 40 to 400° C., and in a temperature-loss tangent (tan δ) curve obtained, a temperature at which tan δ is a maximum value is read as a glass transition temperature (Tg).

From a glass transition temperature Tg(100′) of the laminate (100′) and a glass transition temperature Tg(40′) of the laminate (40′), the rate of change in a glass transition temperature according to a heat and pressure treatment time is calculated by the following formula (1′).

$$Rate of change in glass transition temperature according to heat and pressure treatment time ( \% ) = [ Tg ( {100}^{′} ) - Tg ( {40}^{′} ) ] \times 100 / Tg ( {100}^{′} ) \qquad ( {1}^{′} )$$

### Advantageous Effects of Invention

According to the present embodiment, it is possible to provide a resin composition that exhibits a small change in the conductor adhesion even when a heat and pressure treatment time is varied, and a prepreg, a laminate, a resin film, a printed wiring board, and a semiconductor package in each of which the resin composition is used.

### DESCRIPTION OF EMBODIMENTS

In this description, the numerical range shown with “to” represents a range including the numerical values before and after the “to” as the maximum value and the minimum value.

For example, an expression of the numerical range “X to Y” (X and Y are real numbers) means a numerical range of X or more and Y or less. The expression of “X or more” in this description means X and numerical values exceeding X. The expression “Y or less” in this description means Y and numerical values less than Y.

The lower limit and the upper limit of a numerical range described in this description can be appropriately combined with the upper limit and the lower limit of another numerical range, respectively.

In a numerical range described in this description, the upper limit and the lower limit of the numerical range may each be substituted with a value shown in Examples.

Unless otherwise specified, as each component and material exemplified in this description, one kind may be used alone or two or more kinds may be used in combination.

In this description, when multiple substances corresponding to each component are present in a resin composition, unless otherwise specified, the content of the component in the resin composition means the total amount of the multiple substances present in the resin composition.

In this description, the “solid component” refers to a component other than a solvent, and a component that is in a liquid form at 25° C. is also considered as a solid component.

In this description, the weight average molecular weight (Mw) means a value measured based on polystyrene by gel permeation chromatography (GPC). Specifically, the weight average molecular weight (Mw) in this description can be measured by a method described in the section of Examples.

The “semi-cured product” in this description is synonymous with a resin composition in a state of B-stage in JIS K 6800 (2006), and the “cured product” is synonymous with a resin composition in a state of C-stage in JIS K 6800 (2006).

An action mechanism described in this description is a presumed matter and does not limit the mechanisms of the advantageous effects of the present embodiment.

An aspect in which matters described in this description are appropriately combined is also included in the present embodiment.

### [Resin Composition]

The Resin Composition of the Present Embodiment is
a resin composition containing a thermosetting resin, and
the resin composition has a rate of change in a glass transition temperature according to a heat and pressure treatment time as measured under the following conditions of −20% to +20%.

### (Measurement Method of Rate of Change in Glass Transition Temperature According to Heat and Pressure Treatment Time)

Seven sheets of a prepreg having a thickness of 0.1 mm and containing the resin composition and a glass cloth (type of glass: T-glass, basis weight: 114 g/m², thickness of glass cloth: 0.098 mm) are stacked and subjected to a heat and pressure treatment under conditions of a temperature of 240° C. and a pressure of 3.0 MPa for 100 minutes or 40 minutes to obtain a laminate (100) produced with a heat and pressure treatment time of 100 minutes and a laminate (40) produced with a heat and pressure treatment time of 40 minutes.

The laminate (40) and the laminate (100) obtained are each cut into a size in the surface direction of 4 mm×30 mm and dried at 105° C. for 1 hour to produce a specimen. The specimen is used as a measurement object and is subjected to a dynamic viscoelasticity measurement using a dynamic viscoelasticity measuring device under conditions of a temperature rising rate of 5° C./minute, a frequency of 10 Hz, and a measuring temperature range of 40 to 400° C., and in a temperature-loss tangent (tan δ) curve obtained, a temperature at which tan δ is a maximum value is read as a glass transition temperature (Tg).

From a glass transition temperature Tg(100) of the laminate (100) and a glass transition temperature Tg(40) of the laminate (40), the rate of change in a glass transition temperature according to a heat and pressure treatment time is calculated by the following formula (1).

$$Rate of change in glass transition temperature according to heat and pressure treatment time ( \% ) = [ Tg ( 100 ) - Tg ( 40 ) ] \times 100 / Tg ( 100 ) \qquad ( 1 )$$

### [Physical Properties of Resin Composition]

### <Rate of Change in Glass Transition Temperature According to Heat and Pressure Treatment Time>

The resin composition of the present embodiment has a rate of change in a glass transition temperature according to a heat and pressure treatment time of −20% to +20%.

Since the rate of change in the glass transition temperature according to the heat and pressure treatment time is −20% to +20%, even when the heat and pressure treatment time is varied, the resin composition of the present embodiment exhibits a small change in the conductor adhesion. This is supposedly because, when the rate of change in the glass transition temperature according to the heat and pressure treatment time is-20% to +20%, curing of the resin composition sufficiently proceeds in a relatively short period of time.

A more detailed measurement method of the rate of change in the glass transition temperature according to the heat and pressure treatment time is as described in the section of Examples.

The rate of change in the glass transition temperature according to the heat and pressure treatment time is, from the viewpoint of achieving a smaller change in the conductor adhesion according to the heat and pressure treatment time, preferably −15% to +15%, more preferably −12% to +12%, further preferably −10% to +10%, furthermore preferably −8% to +8%, furthermore preferably −7% to +7%, furthermore preferably −6% to +6%, and particularly preferably −5% to +5%.

An example of effective methods for adjusting the rate of change in the glass transition temperature according to the heat and pressure treatment time to −20% to +20% is adjusting the composition of the resin composition to a composition in which a high degree of curing can be achieved in a short period time, a composition in which a reaction starts at a lower activation energy and a high crosslinking density can be formed, and the like.

### <Glass Transition Temperature of Laminate (40)>

When the resin composition of the present embodiment is in the form of the laminate (40) in the “Measurement method of rate of change in glass transition temperature according to heat and pressure treatment time”, the glass transition temperature Tg(40) of the laminate (40) is, from the viewpoint of achieving a smaller change in the conductor adhesion according to the heat and pressure treatment time, preferably 200 to 400° C., more preferably 240 to 370° C., further preferably 255 to 350° C., and particularly preferably 260 to 330° C.

### <Coefficient of Thermal Expansion of Laminate (40)>

When the resin composition of the present embodiment is in the form of the laminate (40) in the “Measurement method of rate of change in glass transition temperature according to heat and pressure treatment time”, the coefficient of thermal expansion of the laminate (40) is, from the viewpoint of achieving a smaller change in the conductor adhesion according to the heat and pressure treatment time, preferably 4.5 to 25.0 ppm/° C., more preferably 5.0 to 20.0 ppm/° C., further preferably 5.5 to 13.0 ppm/° C., and particularly preferably 6.0 to 11.0 ppm/° C.

The coefficient of thermal expansion of the laminate (40) can be measured by a method described in the section of Examples.

### <Bending Elastic Modulus of Laminate (40)>

When the resin composition of the present embodiment is in the form of the laminate (40) in the “Measurement method of rate of change in glass transition temperature according to heat and pressure treatment time”, the bending elastic modulus of the laminate (40) is, from the viewpoint of achieving a smaller change in the conductor adhesion according to the heat and pressure treatment time, preferably 25 to 50 GPa, more preferably 30 to 45 GPa, further preferably 33 to 42 GPa, and particularly preferably 34 to 40 GPa.

The bending elastic modulus of the laminate (40) can be measured by a method described in the section of Examples.

Note that the “T-glass” in the present embodiment is a glass having a composition of SiO₂ (64 to 66% by mass), Al₂O₃ (24 to 26% by mass), and MgO (9 to 11% by mass).

### [Composition of Resin Composition]

Next, components that the resin composition of the present embodiment contains will be described.

The resin composition of the present embodiment contains a thermosetting resin (hereinafter also referred to as “thermosetting resin (A)”).

In this description, each component is sometimes referred to as an abbreviation, such as component (A), and other components are also sometimes abbreviated in the same manner.

### <(A) Thermosetting Resin>

Examples of the thermosetting resin (A) include a maleimide resin, an epoxy resin, a phenol resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, and a melamine resin. Among them, a maleimide resin, an epoxy resin, and a phenol resin are preferred.

As the thermosetting resin (A), one kind may be used alone or two or more kinds may be used in combination.

### (Maleimide Resin)

As the maleimide resin, one or more selected from the group consisting of a maleimide resin having one or more N-substituted maleimide groups and a derivative thereof are preferred.

In the following explanation, a maleimide resin having one or more N-substituted maleimide groups is sometimes referred to as “maleimide resin (AX)” or “component (AX)”.

A derivative of a maleimide resin having one or more N-substituted maleimide groups is sometimes referred to as “maleimide resin derivative (AY)” or “component (AY)”.

### (Maleimide Resin (AX))

The maleimide resin (AX) is not particularly limited as long as it is a maleimide resin having one or more N-substituted maleimide groups.

The maleimide resin (AX) is, from the viewpoints of the conductor adhesion and heat resistance, preferably an aromatic maleimide resin having two or more N-substituted maleimide groups, and more preferably an aromatic bismaleimide resin having two N-substituted maleimide groups.

In this description, the “aromatic maleimide resin” means a compound having an N-substituted maleimide group directly bonded to an aromatic ring. In this description, the “aromatic bismaleimide resin” means a compound having two N-substituted maleimide groups directly bonded to an aromatic ring. In this description, the “aromatic polymaleimide resin” means a compound having three or more N-substituted maleimide groups directly bonded to the aromatic ring. In this description, the “aliphatic maleimide resin” means a compound having an N-substituted maleimide group directly bonded to an aliphatic hydrocarbon.

As the maleimide resin (AX), a maleimide resin represented by the following general formula (A-1) is preferred.

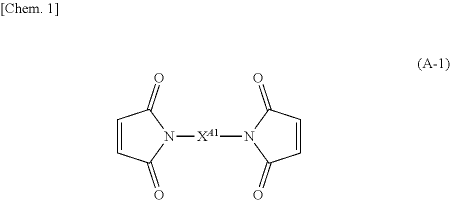

(In the formula, X^{A1} is a divalent organic group.)

Examples of the divalent organic group represented by X^{A1} in the general formula (A-1) include divalent organic groups represented by the following general formula (A-2), the following general formula (A-3), the following general formula (A-4), the following general formula (A-5), or the following general formula (A-6).

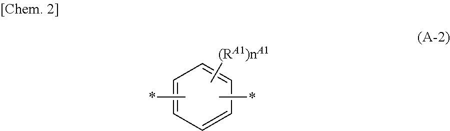

(In the formula, R^{A1} is an aliphatic hydrocarbon group having 1 to 5 carbon atoms or a halogen atom. n^{A1} is an integer of 0 to 4. * represents a bonding site.)

Examples of the aliphatic hydrocarbon group having 1 to 5 carbon atoms represented by R^{A1} in the general formula (A-2) include alkyl groups having 1 to 5 carbon atoms, such as a methyl group, an ethyl group, an n-propyl group, an isopropyl group, an n-butyl group, an isobutyl group, a t-butyl group, and an n-pentyl group; alkenyl groups having 2 to 5 carbon atoms; and alkynyl groups having 2 to 5 carbon atoms. The aliphatic hydrocarbon group having 1 to 5 carbon atoms may be linear or branched.

Examples of the halogen atom include a fluorine atom, a chlorine atom, a bromine atom, and an iodine atom.

When n^{A1} is an integer of 2 or more, the multiple RAI groups may be the same or different.

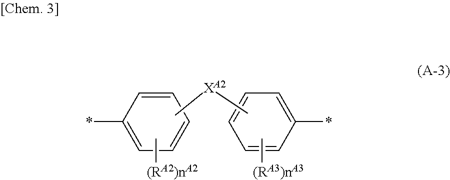

(In the formula, R^{A2} and R^{A3} are each independently an aliphatic hydrocarbon group having 1 to 5 carbon atoms or a halogen atom. X^{A2} is an alkylene group having 1 to 5 carbon atoms, an alkylidene group having 2 to 5 carbon atoms, an ether group, a sulfide group, a sulfonyl group, a carbonyloxy group, a keto group, a single bond, or a divalent organic group represented by the following general formula (A-3-1). n^{A2} and n^{A3} are each independently an integer of 0 to 4. * represents a binding site.)

Examples of the aliphatic hydrocarbon group having 1 to 5 carbon atoms and the halogen atom represented by R^{A2} and R^{A3} in the general formula (A-3) include the same examples as for R^{A1} described above.

Examples of the alkylene group having 1 to 5 carbon atoms represented by X^{A2} in the general formula (A-3) include a methylene group, a 1,2-dimethylene group, a 1,3-trimethylene group, a 1,4-tetramethylene group, and a 1,5-pentamethylene group. As the alkylene group having 1 to 5 carbon atoms, a methylene group is preferred.

Examples of the alkylidene group having 2 to 5 carbon atoms represented by X^{A2} in the general formula (A-3) include an ethylidene group, a propylidene group, an isopropylidene group, a butylidene group, an isobutylidene group, a pentylidene group, and an isopentylidene group.

n^{A2} and n^{A3} in the general formula (A-3) are each independently an integer of 0 to 4, and from the viewpoint of availability, are each preferably an integer of 0 to 2.

When n^{A2} or n^{A3} are an integer of 2 or more, the multiple R^{A2} groups or the multiple R^{A3} groups may be the same or different.

The divalent organic group represented by the general formula (A-3-1) represented by X^{A2} in the general formula (A-3) is as follows.

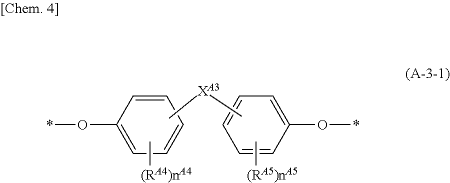

(In the formula, R^{A4} and R^{A5} are each independently an aliphatic hydrocarbon group having 1 to 5 carbon atoms or a halogen atom. X^{A3} is an alkylene group having 1 to 5 carbon atoms, an alkylidene group having 2 to 5 carbon atoms, an ether group, a sulfide group, a sulfonyl group, a carbonyloxy group, a keto group, or a single bond. n^{A4} and n^{A5} are each independently an integer of 0 to 4. * represents a binding site.)

Examples of the aliphatic hydrocarbon group having 1 to 5 carbon atoms and the halogen atom represented by R^{A4} and R^{A5} in the general formula (A-3-1) include the same examples as for R^{A1} described above.

Examples of the alkylene group having 1 to 5 carbon atoms and the alkylidene group having 2 to 5 carbon atoms represented by X^{A3} in the general formula (A-3-1) include the same examples as for X^{A2} described above.

n^{A4} and n^{A5} in the general formula (A-3-1) are each independently an integer of 0 to 4, and from the viewpoint of availability, are each preferably an integer of 0 to 2.

When n^{A4} or n^{A5} are an integer of 2 or more, the multiple R^{A4} groups or the multiple R^{A5} groups may be the same or different.

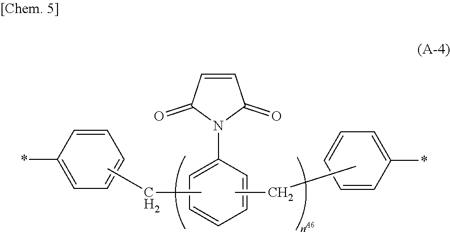

(In the formula, n^{A6} is an integer of 0 to 10. * represents a binding site.)

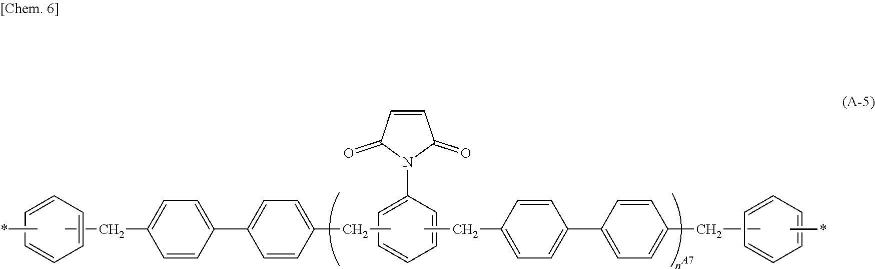

(In the formula, n^{A7} is a number of 0 to 5. * represents a binding site.)

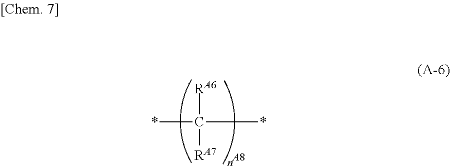

(In the formula, R^{A6} and R^{A7} are each independently a hydrogen atom or an aliphatic hydrocarbon group having 1 to 5 carbon atoms. n^{A8} is an integer of 1 to 8. * represents a binding site.)

Examples of the aliphatic hydrocarbon group having 1 to 5 carbon atoms and the halogen atom represented by R^{A6} and R^{A7} in the general formula (A-6) include the same examples as for R^{A1} described above.

When n^{A8} in the general formula (A-6) is an integer of 2 or more, the multiple R^{A6} groups or the multiple R^{A7} groups may be the same or different.

Examples of the maleimide resin (AX) include an aromatic bismaleimide resin, an aromatic polymaleimide resin, and an aliphatic maleimide resin, and among them, an aromatic bismaleimide resin is preferred. In other words, the component (A) is preferably one or more selected from the group consisting of an aromatic maleimide resin having two or more N-substituted maleimide groups and a derivative thereof.

As the maleimide resin (AX), from the viewpoints of the heat resistance, dielectric characteristics, and the like, bis(4-maleimidophenyl) methane, m-phenylenebismaleimide, 2,2-bis[4-(4-maleimidophenoxy)phenyl]propane, 4-methyl-1,3-phenylenebismaleimide, 3,3′-dimethyl-5,5′-diethyl-4,4′-diphenylmethanebismaleimide, polyphenylmethane maleimide, an aromatic bismaleimide resin having an indane skeleton, and a biphenylaralkyl-type maleimide resin are preferred.

As the maleimide resin derivative (AY), an aminomaleimide resin which has a structure derived from the maleimide resin (AX) and a structure derived from a diamine compound is preferred.

The aminomaleimide resin is obtained, for example, by subjecting the maleimide resin (AX) and a diamine compound to Michael addition.

As the diamine compound, for example, one similar to an amine compound having at least two primary amino groups in one molecule mentioned in JP 2020-200406 A can be used. Among them, 4,4′-diaminodiphenylmethane, 3,3′-dimethyl-4,4′-diaminodiphenylmethane, 3,3′-diethyl-4,4′-diaminodiphenylmethane, 2,2-bis[4-(4-aminophenoxy)phenyl]propane, 4,4′-[1,3-phenylenebis(1-methylethylidene)]bisaniline, 4,4′-[1,4-phenylenebis(1-methylethylidene)]bisaniline, 3,3′-diethyl-4,4′-diaminodiphenylmethane, and a silicone compound having a primary amino group on both the terminals thereof are preferred.

The content of the structure derived from the maleimide resin (AX) in the aminomaleimide resin is preferably 5 to 95% by mass, more preferably 30 to 93% by mass, and further preferably 70 to 90% by mass.

The content of the structure derived from a diamine compound in the aminomaleimide resin is preferably 5 to 95% by mass, more preferably 7 to 70% by mass, and further preferably 10 to 30% by mass.

When the resin composition of the present embodiment contains a maleimide resin, the content of the maleimide resin is, from the viewpoints of the heat resistance, moldability, processability, conductor adhesion, and dielectric characteristics, based on the total amount (100% by mass) of the resin components in the resin composition of the present embodiment, preferably 1 to 90% by mass, more preferably 20 to 80% by mass, further preferably 35 to 75% by mass, and particularly preferably 50 to 70% by mass.

Here, in this description, the “resin component” means a resin and a compound that forms a resin through a curing reaction.

In the resin composition of the present embodiment, for example, the component (A), a component (B) described later, and a component (D) described later each correspond to a resin component.

When the resin composition of the present embodiment contains, as an optional component, a resin or a compound that forms a resin through a curing reaction other than the components described above, the optional component is also encompassed in the resin component.

On the other hand, the component (C) described later is not encompassed in the resin component.

The total content of the resin components in the resin composition of the present embodiment is, from the viewpoints of the low thermal expansion, heat resistance, flame retardance, and conductor adhesion, based on the total amount (100% by mass) of the solid components in the resin composition of the present embodiment, preferably 10 to 70% by mass, more preferably 15 to 50% by mass, and further preferably 20 to 40% by mass.

### (Epoxy Resin)

Examples of the epoxy resin include bisphenol-type epoxy resins, such as a bisphenol A-type epoxy resin, a bisphenol F-type epoxy resin, and a bisphenol S-type epoxy resin; novolac-type epoxy resins, such as a bisphenol A novolac-type epoxy resin, a bisphenol F novolac-type epoxy resin, a phenol novolac-type epoxy resin, a cresol novolac-type epoxy resin, a biphenyl novolac-type epoxy resin, and a naphthol novolac-type epoxy resin; aralkyl-type epoxy resins, such as a phenol aralkyl-type epoxy resin, a biphenyl aralkyl-type epoxy resin, and a naphthol aralkyl-type epoxy resin; a stilbene-type epoxy resin; a naphthylene ether-type epoxy resin; a biphenyl-type epoxy resin; a dihydroanthracene-type epoxy resin; an epoxy resin containing a saturated dicyclopentadiene skeleton; a cyclohexanedimethanol-type epoxy resin; a spiro-ring-containing epoxy resin; a heterocyclic epoxy resin; an alicyclic epoxy resin; an aliphatic chain epoxy resin; and a rubber-modified epoxy resin.

When the resin composition of the present embodiment contains an epoxy resin, the content of the epoxy resin is, from the viewpoints of the heat resistance, moldability, processability, conductor adhesion, and dielectric characteristics, based on the total amount (100% by mass) of the resin components in the resin composition of the present embodiment, preferably 1 to 25% by mass, more preferably 5 to 20% by mass, and further preferably 8 to 15% by mass.

### (Phenol Resin)

Examples of the phenol resin include novolac-type phenol resins, such as a phenol novolac resin and a cresol novolac resin; a naphthalene-type phenol resin, a high-ortho-type novolac phenol resin, a terpene-modified phenol resin, a terpene phenol-modified phenol resin, an aralkyl-type phenol resin, a dicyclopentadiene-type phenol resin, a salicylaldehyde-type phenol resin, and a benzaldehyde-type phenol resin.

When the resin composition of the present embodiment contains a phenol resin, the content of the phenol resin is, from the viewpoints of the heat resistance, moldability, processability, conductor adhesion, and dielectric characteristics, based on the total amount (100% by mass) of the resin components in the resin composition of the present embodiment, preferably 3 to 30% by mass, more preferably 8 to 25% by mass, and further preferably 12 to 20% by mass.

The content of the thermosetting resin (A) in the resin composition of the present embodiment is, from the viewpoints of the heat resistance, moldability, processability, conductor adhesion, and dielectric characteristics, based on the total amount (100% by mass) of the resin components in the resin composition of the present embodiment, preferably 20 to 98% by mass, more preferably 40 to 96% by mass, further preferably 60 to 94% by mass, and particularly preferably 80 to 92% by mass.

When the content of the thermosetting resin (A) is the lower limit or more, the heat resistance, moldability, processability, and conductor adhesion tend to be better. When the content of the thermosetting resin (A) is the upper limit or less, the dielectric characteristics tend to be better.

### <(B) Compound Having a Vinylbenzyl Group>

When the resin composition of the present embodiment contains a maleimide resin as the component (A), the resin composition of the present embodiment preferably further contains a compound having a vinylbenzyl group (B) (hereinafter also referred to as “vinylbenzyl compound (B)”).

When the resin composition of the present embodiment contains the maleimide resin and the vinylbenzyl compound (B), the rate of change in the glass transition temperature according to the heat and pressure treatment time tends to be easily adjusted to −20% to +20%. The reason thereof is not clear, but a factor is supposedly that N-substituted maleimide groups of the maleimide resin and vinylbenzyl groups of the vinylbenzyl compound (B) react at a relatively low temperature to generate radicals, which promote the curing reaction of the maleimide resin.

As the vinylbenzyl compound (B), one kind may be used alone or two or more kinds may be used in combination.

The vinylbenzyl group of the vinylbenzyl compound (B) may be any of an o-vinylbenzyl group, a m-vinylbenzyl group, and a p-vinylbenzyl group, but from the viewpoint of the dielectric characteristics, a p-vinylbenzyl group and a m-vinylbenzyl group are preferred.

The content of the p-vinylbenzyl groups in all the vinylbenzyl groups of the vinylbenzyl compound (B) is, from the viewpoint of the low dielectric tangent, preferably 10 to 100% by mass, more preferably 20 to 90% by mass, further preferably 30 to 80% by mass, and particularly preferably 40 to 60% by mass. The content of the m-vinylbenzyl groups in all the vinylbenzyl groups of the vinylbenzyl compound (B) is, from the viewpoint of the low dielectric tangent, preferably 10 to 100% by mass, more preferably 20 to 90% by mass, further preferably 30 to 80% by mass, and particularly preferably 40 to 60% by mass.

The compound having a vinylbenzyl group (B) preferably contains one or more selected from the group consisting of (B1) a compound having one or more vinylbenzyl groups directly bonded to a carbon atom and (B2) a compound having three or more vinylbenzyl groups directly bonded to an oxygen atom.

### ((B1) Compound Having One or More Vinylbenzyl Groups Directly Bonded to a Carbon Atom)

The component (B1) is not particularly limited as long as it is a compound having one or more vinylbenzyl groups directly bonded to a carbon atom.

When the resin composition of the present embodiment contains the component (B1) as the vinylbenzyl compound (B), the rate of change in the glass transition temperature according to the heat and pressure treatment time tends to be easily adjusted to −20% to +20%, and superior dielectric characteristics tend to be achieved.

The number of the vinylbenzyl groups directly bonded to a carbon atom in one molecule of the component (B1) can be any of one or more, but the component (B1) is preferably a compound having two or more vinylbenzyl groups directly bonded to a carbon atom, more preferably a compound having two to four vinylbenzyl groups directly bonded to a carbon atom, and further preferably a compound having two or three vinylbenzyl groups directly bonded to a carbon atom.

The weight average molecular weight (Mw) of the component (B1) is, from the viewpoints of the moldability and handleability, preferably 200 to 800, more preferably 250 to 750, and further preferably 300 to 700.

The vinylbenzyl compound (B) preferably contains the component (B1), the component (B1) being a compound containing a condensed polycyclic structure containing an aromatic ring and a non-aromatic ring.

Examples of the condensed polycyclic structure containing an aromatic ring and a non-aromatic ring in the component (B1) include an indene ring, a fluorene ring, an indane ring, a phenanthrene ring, and an acenaphthylene ring. Among them, from the viewpoint of the dielectric characteristics, an indene ring and a fluorene ring are preferred.

As the component (B1) containing an indene ring, from the viewpoint of the dielectric characteristics, a compound represented by the following general formula (B1-1) is preferred.

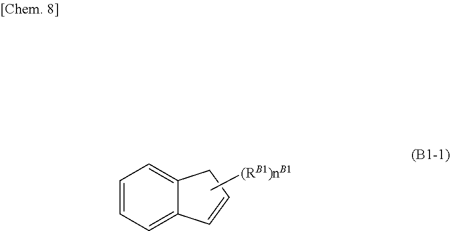

(In the formula, R^{B1} groups are each independently a vinylbenzyl group, and n^{B1} is an integer of 1 to 3.)

The compound represented by the general formula (B1-1) may be any of a compound having one vinylbenzyl group, a compound having two vinylbenzyl groups, and a compound having three vinylbenzyl groups, or may be a mixture thereof.

When the compound is a mixture, an average number of the vinylbenzyl groups in one molecule of the compound represented by the general formula (B1-1) is preferably 1.4 to 2.8, more preferably 1.6 to 2.7, and further preferably 1.8 to 2.6.

As the component (B1) containing a fluorene group, from the viewpoint of the dielectric characteristics, a compound represented by the following general formula (B1-2) is preferred.

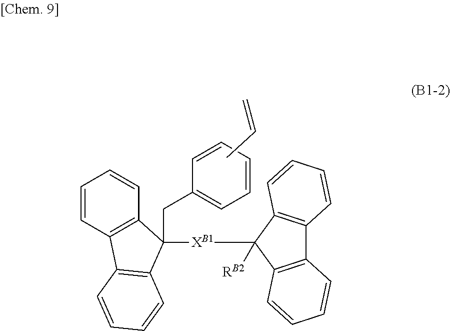

(In the formula, X^{B1} is an alkylene group having 1 to 10 carbon atoms, and R^{B2} is a hydrogen atom or a vinylbenzyl group.)

Examples of the alkylene group having 1 to 10 carbon atoms represented by X^{B1} in the general formula (B1-2) include a methylene group, a 1,2-dimethylene group, a 1,3-trimethylene group, a 1,4-tetramethylene group, a 1,5-pentamethylene group, and a 1,6-hexamethylene group.

### ((B2) Compound Having Three or More Vinylbenzyl Groups Directly Bonded to an Oxygen Atom)

The component (B2) is not particularly limited as long as it is a compound having three or more vinylbenzyl groups directly bonded to an oxygen atom.

When the resin composition of the present embodiment contains the component (B2) as the vinylbenzyl compound (B), the rate of change in the glass transition temperature according to the heat and pressure treatment time tends to be easily adjusted to −20% to +20% and the dielectric characteristics and curability tend to be able to be enhanced.

The vinylbenzyl compound (B) preferably contains the component (B2), the component (B2) being a compound represented by the following general formula (B2-1) from the viewpoint of the curability, moldability, and handleability.

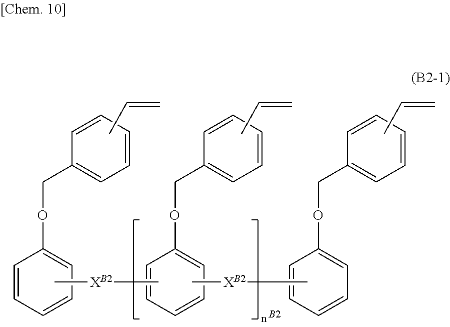

(In the formula, X^{B2} groups are each independently a divalent hydrocarbon group and n^{B2} is an integer of 1 to 5.)

Examples of the divalent hydrocarbon group represented by X^{B2} in the general formula (B2-1) include an alkylene group having 1 to 5 carbon atoms, an alkylidene group having 2 to 5 carbon atoms, a divalent alicyclic hydrocarbon group having 5 to 12 carbon atoms, an arylene group having 6 to 12 carbon atoms, and a divalent group of a combination thereof.

Examples of the alkylene group having 1 to 5 carbon atoms include a methylene group, a 1,2-dimethylene group, a 1,3-trimethylene group, a 1,4-tetramethylene group, and a 1,5-pentamethylene group.

Examples of the alkylidene group having 2 to 5 carbon atoms include an ethylidene group, a propylidene group, an isopropylidene group, a butylidene group, an isobutylidene group, a pentylidene group, and an isopentylidene group.

Examples of the divalent alicyclic hydrocarbon group having 5 to 12 carbon atoms include a divalent group obtained by eliminating two hydrogen atoms that are bonded to different two carbon atoms from an alicyclic hydrocarbon compound, such as norbornane, decalin, bicycloundecane, or saturated dicyclopentadiene.

Examples of the arylene group having 6 to 12 carbon atoms include a phenylene group, a naphthylene group, and a biphenylene group.

X^{B2} is preferably a group in which an alkylene group having 1 to 5 carbon atoms and an arylene group having 6 to 12 carbon atoms are combined, and more preferably a divalent group represented by the following general formula (B2-2-1).

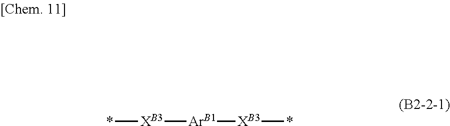

(In the formula, X^{B3} groups are each independently an alkylene group having 1 to 5 carbon atoms and Ar^{B1} is an arylene group having 6 to 12 carbon atoms. * represents a binding site.)

The alkylene group having 1 to 5 carbon atoms represented by X^{B3} is preferably a methylene group among others mentioned above as examples of X^{B2}.

The arylene group having 6 to 12 carbon atoms represented by Ar^{B1} is preferably a phenylene group and a biphenylene group among others mentioned above as examples of X^{B2}. The phenylene group is preferably a 1,4-phenylene group, and the biphenylene group is preferably a 4,4′-biphenylene group.

n^{B2} in the general formula (B2-1) is an integer of 1 to 50, preferably an integer of 1 to 30, and more preferably an integer of 1 to 20.

As the vinylbenzyl compound (B), a commercially available product may be used or one synthesized by a known method may be used.

An example of the method for synthesizing the vinylbenzyl compound (B) is a method in which a base compound for introducing a vinylbenzyl group and a styrene having a halogenated methyl group are reacted in the presence of a basic compound. Examples of the base compound include a compound having a phenolic hydroxy group; and a compound having a condensed polycyclic structure containing an aromatic ring and a non-aromatic ring, such as fluorene, indene, indane, phenanthrene, or acenaphthylene.

Examples of the styrene having a halogenated methyl group include an o-chloromethylstyrene, a m-chloromethylstyrene, a p-chloromethylstyrene, and a mixture thereof.

Examples of the basic compound include an alkali metal hydroxide and an alkali metal alkoxide.

In the above reaction, a phase transfer catalyst may be used. An example of the phase transfer catalyst is tetrabutylammonium bromide.

The reaction is preferably performed with heat and with stirring, and the resulting product may be purified by a known method, such as concentration, reprecipitation, or washing, as required.

The total content of one or more selected from the group consisting of the component (B1) and component (B2) in the vinylbenzyl compound (B) is, from the viewpoint of the dielectric characteristics, based on the total amount of the vinylbenzyl compound (B), preferably 80 to 100% by mass, more preferably 90 to 100% by mass, and further preferably 95 to 100% by mass.

The content of the vinylbenzyl compound (B) in the resin composition of the present embodiment is, based on the total amount (100% by mass) of the resin components in the resin composition of the present embodiment, preferably 1 to 80% by mass, more preferably 3 to 50% by mass, further preferably 6 to 35% by mass, and particularly preferably 8 to 20% by mass.

When the content of the vinylbenzyl compound (B) is the lower limit or more, the rate of change in the glass transition temperature according to the heat and pressure treatment time tends to be easily adjusted to −20% to +20%. When the content of the vinylbenzyl compound (B) is the upper limit or less, the conductor adhesion tends to be better.

When the resin composition of the present embodiment contains the maleimide resin and the vinylbenzyl compound (B), the ratio of the content by mass of the vinylbenzyl compound (B) to the content by mass of the maleimide resin[vinylbenzyl compound (B)/maleimide resin] (hereinafter also referred to as “content ratio [vinylbenzyl compound (B)/maleimide resin]”) in the resin composition of the present embodiment is, from the viewpoint of easy adjustment of the rate of change in the glass transition temperature according to the heat and pressure treatment time to −20% to +20%, preferably 0.11 or more, more preferably 0.12 or more, further preferably 0.13 or more, and particularly preferably 0.14 or more.

The content ratio [vinylbenzyl compound (B)/maleimide resin] is, from the viewpoint of the conductor adhesion, preferably 50 or less, more preferably 10 or less, further preferably 1 or less, and particularly preferably 0.3 or less.

The content ratio [vinylbenzyl compound (B)/maleimide resin] is, from the same point of view, preferably 0.11 to 50, more preferably 0.12 to 10, further preferably 0.13 to 1, and particularly preferably 0.14 to 0.3.

As described above, as the resin composition of the present embodiment, one containing a maleimide resin and the vinylbenzyl compound (B) is preferred, but, as required, the resin composition of the present embodiment may be one that does not contain a maleimide resin and contains the vinylbenzyl compound (B).

### < (C) Inorganic Filler>

The resin composition of the present embodiment preferably further contains an inorganic filler (C).

When the resin composition of the present embodiment contains the inorganic filler (C), the low thermal expansion and the heat resistance tend to be better.

As the inorganic filler (C), one kind may be used alone or two or more kinds may be used in combination.

Examples of the inorganic filler (C) include silica, alumina, titanium oxide, mica, beryllia, barium titanate, potassium titanate, strontium titanate, calcium titanate, aluminum carbonate, magnesium hydroxide, aluminum hydroxide, aluminum silicate, calcium carbonate, calcium silicate, magnesium silicate, silicon nitride, boron nitride, clay, talc, aluminum boron, and silicon carbide. Among them, from the viewpoints of the low thermal expansion, heat resistance, and flame retardance, silica, alumina, mica, and talc are preferred, silica and alumina are more preferred, and silica is further preferred.

As the silica, from the viewpoints of the dispersibility and moldability, fused silica is preferred.

The average particle diameter (D₅₀) of the inorganic filler (C) is, from the viewpoints of the dispersibility of the inorganic filler (C) and the fine wiring property, preferably 0.1 to 10 μm, more preferably 0.2 to 1 μm, and further preferably 0.3 to 0.8 μm.

In this description, the average particle diameter (D₅₀) of the inorganic filler (C) is a particle diameter of a point corresponding to a volume of 50% in a cumulative frequency distribution curve based on the particle diameter determined with the entire volume of the particles taken as 100%. The average particle diameter of the inorganic filler (C) can be measured, for example, with a particle size distribution analyzer using a laser diffraction scattering method.

Examples of the shape of the inorganic filler (C) include a spherical shape and a crushed shape, and a spherical shape is preferred.

From the viewpoint of enhancing the dispersibility and adhesion with organic components, the inorganic filler (C) may be surface-treated with a surface treating agent, such as a silane coupling agent.

When the resin composition of the present embodiment contains the inorganic filler (C), the content of the inorganic filler (C) based on the total amount (100% by mass) of the solid components of the resin composition is preferably 20 to 95% by mass, more preferably 40 to 90% by mass, and further preferably 60 to 80% by mass.

When the content of the inorganic filler (C) is the lower limit or more, the low thermal expansion and heat resistance tend to be better. When the content of the inorganic filler (C) is the upper limit or less, the moldability and conductor adhesion tend to be better.

### < (D) Curing Accelerator>

The resin composition of the present embodiment preferably further contains a curing accelerator (D).

When the resin composition of the present embodiment contains the curing accelerator (D), the curability tends to be enhanced and the dielectric characteristics, heat resistance, and conductor adhesion tend to be better.

As the curing accelerator (D), one kind may be used alone or two or more kinds may be used in combination.

Examples of the curing accelerator (D) include an acidic catalyst, such as p-toluenesulfonic acid; amine compounds, such as triethylamine, tributylamine, pyridine, and dicyandiamide; imidazole compounds, such as methylimidazole, phenylimidazole, 2-undecylimidazole, 1-cyanoethyl-2-phenylimidazole, and 1-cyanoethyl-2-phenylimidazolium trimellitate; an isocyanate-masked imidazole compound, such as an addition reaction product of a hexamethylene diisocyanate resin and 2-ethyl-4-methylimidazole; a quaternary ammonium compound; phosphorous compounds, such as triphenylphosphine and a quaternary phosphonium compound which is an addition reaction product of p-benzoquinone and tri-n-butylphosphine; organic peroxides, such as dicumyl peroxide, 2,5-dimethyl-2,5-bis(t-butylperoxy) hexyne-3, 2,5-dimethyl-2,5-bis(t-butylperoxy) hexane, t-butyl peroxyisopropyl monocarbonate, and α,α′-bis(t-butylperoxy)diisopropylbenzene; inorganic peroxides, such as potassium persulfate, sodium persulfate, and ammonium persulfate; azo compounds, such as 2,2′-azobisisobutyronitrile, 2,2′-azobis(2,4-dimethylvaleronitrile), and 2,2′-azobis(4-methoxy-2′-dimethylvaleronitrile); carboxylic acid salts of manganese, cobalt, zinc, and the like; and an acidic catalyst, such as p-toluenesulfonic acid. Among them, from the viewpoints of the curing accelerating effect and storage stability, an isocyanate-masked imidazole compound is preferred.

When the resin composition of the present embodiment contains the curing accelerator (D), the content of the curing accelerator (D) based on 100 parts by mass of the thermosetting resin (A) is preferably 0.01 to 10 parts by mass, more preferably 0.1 to 7 parts by mass, and further preferably 0.2 to 5 parts by mass.

When the content of the curing accelerator (D) is the lower limit or more, a sufficient curing accelerating effect tends to be easily achieved. When the content of the curing accelerator (D) is the upper limit or less, the storage stability tends to be better.

### <Other Optional Components>

The resin composition of the present embodiment may further contain other optional components, such as a resin material other than the aforementioned components, and a flame retardant, an antioxidant, a heat stabilizer, an antistatic agent, a UV absorber, a pigment, a colorant, a lubricant, a silane coupling agent, an organic solvent, and other additives, as needed.

As each of the other optional components, one kind may be used alone or two or more kinds may be used in combination.

The content of the optional components in the resin composition of the present embodiment is not particularly limited, and the optional components can be used according to the need to the extent that the effects of the present embodiment are not impaired.

The resin composition of the present embodiment may be one that does not contain the optional components according to the desired performance.

From the viewpoint of the handleability, the resin composition of the present embodiment may contain an organic solvent.

Examples of the organic solvent include alcohol solvents, such as ethanol, propanol, butanol, methylcellosolve, butylcellosolve, and propylene glycol monomethyl ether; ketone solvents, such as acetone, methyl ethyl ketone, methyl isobutyl ketone, and cyclohexanone; an ether solvent, such as tetrahydrofuran; aromatic hydrocarbon solvents, such as toluene, xylene, and mesitylene; nitrogen atom-containing solvents, such as dimethylformamide, dimethylacetamide, and N-methylpyrrolidone; a sulfur atom-containing solvent, such as dimethyl sulfoxide; and an ester solvent, such as γ-butyrolactone.

Among them, from the viewpoint of the solubility, an alcohol solvent, a ketone solvent, a nitrogen atom-containing solvent, and an aromatic hydrocarbon solvent are preferred, a ketone solvent is more preferred, and methyl ethyl ketone is further preferred.

### <Method for Producing Resin Composition>

The resin composition of the present embodiment can be produced by mixing components by a known method. In this case, the components may be dissolved or dispersed with stirring. The conditions, such as the order of mixing, the temperature, and the time are not particularly limited and can be appropriately set according to the types of the raw materials and the like.

### [Prepreg]

The prepreg of a first aspect of the present embodiment is a prepreg containing the resin composition of the present embodiment or a semi-cured product of the resin composition.

The prepreg of a second aspect of the present embodiment is a prepreg that contains a resin composition and a fiber base material, the resin composition containing a thermosetting resin, and that has a rate of change in a glass transition temperature according to a heat and pressure treatment time as measured under the following conditions of −20% to +20%.

### (Measurement Method of Rate of Change in Glass Transition Temperature According to Heat and Pressure Treatment Time)

Two or more sheets of the prepreg are stacked and subjected to a heat and pressure treatment under conditions of a temperature of 240° C. and a pressure of 3.0 MPa for 100 minutes or 40 minutes to obtain a laminate (100′) produced with a heat and pressure treatment time of 100 minutes and a laminate (40′) produced with a heat and pressure treatment time of 40 minutes.

The laminate (40′) and the laminate (100′) obtained are each cut into a size in the surface direction of 4 mm×30 mm and dried at 105° C. for 1 hour to produce a specimen. The specimen is used as a measurement object and is subjected to a dynamic viscoelasticity measurement using a dynamic viscoelasticity measuring device under conditions of a temperature rising rate of 5° C./minute, a frequency of 10 Hz, and a measuring temperature range of 40 to 400° C., and in a temperature-loss tangent (tan δ) curve obtained, a temperature at which tan δ is a maximum value is read as a glass transition temperature (Tg).

From a glass transition temperature Tg(100′) of the laminate (100′) and a glass transition temperature Tg(40′) of the laminate (40′), the rate of change in a glass transition temperature according to a heat and pressure treatment time is calculated by the following formula (1′).

$$Rate of change in glass transition temperature according to heat and pressure treatment time ( \% ) = [ Tg ( {100}^{′} ) - Tg ( {40}^{′} ) ] \times 100 / Tg ( {100}^{′} ) \qquad ( {1}^{′} )$$

In the “Measurement method of rate of change in glass transition temperature according to heat and pressure treatment time” using the prepreg of the second aspect, the number of sheets of the prepreg stacked in producing a laminate is not particularly limited, and can be such a number that gives a specimen with which the dynamic viscoelasticity measurement can be performed using a dynamic viscoelasticity measuring device.

Hereinunder, when “the prepreg of the present embodiment” is simply written, it refers to both of the prepreg of the first aspect and the prepreg of the second aspect.

As the fiber base material that the prepreg of the present embodiment contains, for example, a known fiber base material that is used for various laminates for electrical insulation material can be used.

Examples of the material of the fiber base material include inorganic material fibers, such as E-glass, D-glass, S-glass, and Q-glass; organic fibers, such as polyimide, polyester, and tetrafluoroethylene; and a mixture thereof. The fiber base materials have, for example, a shape of woven fabric, nonwoven fabric, roving, chopped strand mat, or surfacing mat. The fiber base material preferably has a sheet shape.

The prepreg of the present embodiment can be produced, for example, by impregnating a fiber base material with the resin composition or applying the resin composition on a fiber base material, which is then dried with heat to be B-staged.

From the viewpoints of the productivity and an adequate B-staging of the resin composition of the present embodiment, the temperature and time for the drying with heat can be, for example, 50 to 200° C. and 1 to 30 minutes.

The content of the resin composition in the prepreg of the present embodiment is, from the viewpoint of easily achieving good moldability in producing a laminate, preferably 20 to 90% by mass, more preferably 25 to 80% by mass, and further preferably 30 to 75% by mass.

The thickness of the prepreg of the present embodiment is, from the viewpoints of the moldability and the capability of high density wiring, preferably 0.01 to 0.5 mm, more preferably 0.02 to 0.3 mm, and further preferably 0.05 to 0.2 mm.

The prepreg of the second aspect of the present embodiment preferably contains the resin composition of the present embodiment or a semi-cured product of the resin composition and a fiber base material.

When the prepreg of the second aspect of the present embodiment is in the form of the laminate (40′) in the “Measurement method of rate of change in glass transition temperature according to heat and pressure treatment time”, suitable ranges of the glass transition temperature, the coefficient of thermal expansion, and the bending elastic modulus of the laminate (40′) are the same as the suitable ranges of the glass transition temperature, the coefficient of thermal expansion, and the bending elastic modulus of the laminate (40).

### [Resin Film]

The resin film of the present embodiment is a resin film containing the resin composition of the present embodiment or a semi-cured product of the resin composition.

The resin film of the present embodiment can be produced, for example, by applying the resin composition of the present embodiment containing an organic solvent on a support, followed by drying with heat.

Examples of the support include a plastic film, a metal foil, and a release paper.

From the viewpoints of the productivity and an adequate B-staging of the resin composition of the present embodiment, the temperature and time for the drying with heat can be, for example, 50 to 200° C. and 1 to 30 minutes.

When a printed wiring board is produced, the resin film of the present embodiment is preferably used for forming an insulating layer.

### [Laminate]

The laminate of the present embodiment is a laminate including a cured product of the resin composition of the present embodiment and a metal foil.

Note that a laminate including a metal foil is sometimes referred to as a metal-clad laminate.

Examples of the metal for the metal foil include copper, gold, silver, nickel, platinum, molybdenum, ruthenium, aluminum, tungsten, iron, titanium, chromium, and an alloy containing one or more of the metal elements.

The laminate of the present embodiment can be produced, for example, by placing a metal foil on one surface or both the surfaces of the prepreg of the present embodiment, followed by a heat and pressure treatment.

In general, by the heat and pressure treatment, a B-staged prepreg is cured to produce the laminate of the present embodiment.

In the heat and pressure treatment, only one sheet of the prepreg may be used or two or more sheets of the prepreg may be stacked.

For the heat and pressure treatment, for example, a multistage press, a multistate vacuum press, continuous molding, an autoclave molding machine, or the like can be used.

The conditions for the heat and pressure treatment can be, for example, a temperature of 100 to 300° C., a time of 10 to 300 minutes, and a pressure of 1.5 to 5 MPa.

### [Printed Wiring Board]

The printed wiring board of the present embodiment is a printed wiring board including a cured product of the resin composition of the present embodiment.

The printed wiring board of the present embodiment can be produced, for example, by forming a conductor circuit by a known method on one or more selected from the group consisting of a cured product of the prepreg of the present embodiment, a cured product of the resin film of the present embodiment, and the laminate of the present embodiment. In addition, by further applying a multilayer adhesion processing as required, a multilayered printed wiring board can also be produced. The conductor circuit can be formed, for example, by appropriately applying drilling, metal plating, or metal foil etching.

### [Semiconductor Package]

The semiconductor package of a first aspect of the present embodiment is a semiconductor package including the printed wiring board of the present embodiment and a semiconductor element.

The semiconductor package of the first aspect of the present embodiment can be produced, for example, by mounting a semiconductor element, a memory, and the like by a known method on the printed wiring board of the present embodiment.

The semiconductor package of a second aspect of the present embodiment is a semiconductor package including a semiconductor element and a cured product of the resin composition of the present embodiment, the cured product of the resin composition sealing the semiconductor element.

The semiconductor package of the second aspect of the present embodiment can be produced, for example, by a method of covering at least a part of the semiconductor element mounted on a printed wiring board with the resin composition of the present embodiment and curing the resin composition.

### EXAMPLES

The present embodiment will be specifically described below with reference to examples. However, the present embodiment is not to be limited to the examples.

In the examples, the weight average molecular weight (Mw) was measured by the following procedure.

### (Measurement Method of Weight Average Molecular Weight (Mw))

The weight average molecular weight (Mw) was calculated from a calibration curve drawn using standard polystyrenes by gel permeation chromatography (GPC). The calibration curve was drawn by approximation to a cubic equation using standard polystyrenes: TSK standard POLYSTYRENE (Type; A-2500, A-5000, F-20, F-80) [manufactured by Tosoh Corporation, tradename]. The measurement conditions of GPC are shown below.
Apparatus: high performance GPC instrument, HLC-8320GPC
Detector: ultraviolet photometric detector, UV-8320 [manufactured by Tosoh Corporation]
Columns: guard column; TSKgel guard column Super (HZ)-M+column; TSKgel Super Multipore HZ-M×2, reference column; TSKgel Super H-RC×2 (all manufactured by Tosoh Corporation, tradenames)
Column size: 4.6× 20 mm (guard column), 4.6×150 mm (column), 6.0× 150 mm (reference column)
   Eluent: tetrahydrofuran
   Sample concentration: 10 mg/l mL

### Injection: 20 μL or 2 μL

Flow rate: 0.35 mL/minute
Measurement temperature: 40° C.

### Production of Aminomaleimide Resin

### Production Example 1

Into a 2-L reaction vessel equipped with a thermometer, a stirrer, and a water determination receiver with a reflux condenser, the reaction vessel being able to be heated and cooled, 100 g of a both-terminal diamine-modified siloxane (manufactured by Shin-Etsu Chemical Co., Ltd., tradename: X-22-161A, silicone compound having a primary amino group on both terminals, functional group equivalent of amino group: 800 g/mol), 450 g of 2,2-bis[4-(4-maleimidophenoxy)phenyl]propane, and 550 g of propylene glycol monomethyl ether were put, and then, were reacted at 120° C. for 3 hours to produce a solution containing an aminomaleimide resin. The weight average molecular weight (Mw) of the resulting aminomaleimide resin was 2,500.

### Production of Vinylbenzyl Compound

### Production Example 2

Into a 500-mL reaction vessel equipped with a stirrer, a thermometer, a reflux condenser, and a nitrogen inlet, 35.6 g of indene as a base compound and 101.2 g of chloromethylstyrene (manufactured by AGC Seimi Chemical Co., Ltd., a mixture of m-form and p-form, m-form content: 50% by mass, p-form content: 50% by mass), 7.1 g of tetra-n-butylammonium bromide as a phase transfer catalyst, 0.1 g of phenothiazine as a polymerization inhibitor, and 77.6 g of toluene as a solvent were put, and were stirred with heat at 40° C. while blowing nitrogen at a flow rate of 50 ml/minute.

Next, a 48 mass % solution of 46.5 g of sodium hydroxide as a basic compound was dropwise added over 20 minutes, and the mixture was further stirred at 60° C. for 9 hours. Blowing of nitrogen was continued during the reaction. Then, the resultant was cooled to a room temperature (25° C.) and was neutralized with a 10% hydrochloric acid solution, followed by two times of washing with pure water. Subsequently, after toluene was evaporated under a reduced pressure, the resulting viscous liquid was washed with methanol and was dried in vacuum, thereby obtaining a vinylbenzyl compound 1.

It was found by 1H-NMR analysis that the vinylbenzyl compound 1 had a structure in which substantially all of two hydrogen atoms directly bonded to the carbon atom of position 1 of indene represented by the following formula (B1-3) were substituted with a vinylbenzyl group, and corresponded to the component (B1). It was also found by GPC analysis that the vinylbenzyl compound 1 was a mixture of one having two vinylbenzyl groups introduced and one having three vinylbenzyl groups introduced, and the weight average molecular weight (Mw) thereof was 500.

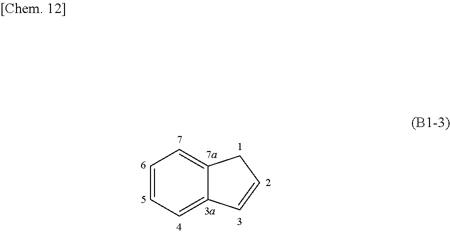

### Production of Resin Composition

### Examples 1 to 9, Comparative Examples 1 to 2

The components shown in Table 1 were mixed in powder forms or blended together with methyl ethyl ketone according to the blending amounts shown in Table 1, and were stirred and mixed at 25° C. to prepare a resin composition of a vanish form (solid concentration: about 60% by mass). In Table 1, the unit of the blending amounts of the components was parts by mass, and in the case of a solution, was parts by mass calculated based on the solid component.

### [Production of Prepreg]

With the thus-obtained resin composition of a vanish form, a glass cloth (Nitto Boseki Co., Ltd., tradename “T2118”, thickness: 0.098 mm, basis weight: 114 g/m², type of glass: T-glass) was impregnated, and was dried with heat at 110° C. for 3 minutes, thereby obtaining a prepreg. The thickness of the obtained prepreg was 0.1 mm, and the content of the resin composition in the prepreg was 48.5% by mass.

### [Production of Copper Clad Laminate]

Seven sheets of the prepreg obtained above were stacked, and a copper foil having a thickness of 12 μm (manufactured by Mitsui Kinzoku Company, tradename “3EC-M3-VLP-12”, Rz of roughened surface: 3.0 μm) was placed over and under the stacked sheets so that a roughened surface was in contact with the prepreg. The stacked body was subjected to a heat and pressure treatment under conditions of a temperature of 240° C. and a pressure of 3.0 MPa for 100 minutes or 40 minutes, thereby producing a copper clad laminate (thickness: 0.7 mm).

### [Evaluation Method and Measurement Method]

The copper clad laminate produced in each example was subjected to measurements and evaluations according to the following methods. The results are shown in Table 1.

### (Measurement Method of Glass Transition Temperature, and Calculation Method of Rate of Change in Glass Transition Temperature According to Heat and Pressure Treatment Time)

The copper foils on both the surfaces of the copper clad laminate produced in each example were removed by etching to obtain a laminate. Among the laminates after removing the copper foils, one produced with a heat and pressure treatment time of 100 minutes in producing the copper clad laminate was taken as a “laminate (100)” and one produced with a heat and pressure treatment time of 40 minutes was taken as a “laminate (40)”.

Each laminate obtained above was cut into a size in the surface direction of 4 mm×30 mm, and was dried at 105° C. for 1 hour to produce a specimen. The specimen was used as a measurement object and was subjected to a dynamic viscoelasticity measurement using a dynamic viscoelasticity measuring device (manufactured by UBM, tradename “Rheogel-E4000”) under conditions of a temperature rising rate of 5° C./minute, a frequency of 10 Hz, and a measurement temperature range of 40 to 400° C. In a temperature-loss tangent (tan δ) curve obtained, the temperature at which tan δ was the maximum value was read as the glass transition temperature (Tg).

In addition, from the glass transition temperature Tg(100) of the laminate (100) and the glass transition temperature Tg(40) of the laminate (40), the rate of change in the glass transition temperature according to the heat and pressure treatment time was calculated by the following formula (1).

$$Rate of change in glass transition temperature according to heat and pressure treatment time ( \% ) = [ Tg ( 100 ) - Tg ( 40 ) ] \times 100 / Tg ( 100 ) \qquad ( 1 )$$

### (Measurement Method of Coefficient of Thermal Expansion)

The laminate (40) and the laminate (100) were each cut into a 5 mm square and dried at 105° C. for 1 hour to produce a specimen. The specimen was mounted on a thermomechanical analyzer (TMA) (manufactured by TA Instruments Japan Inc., tradename “TMA450”) in a direction for detecting the displacement in the thickness direction of the laminate, and was subjected to a thermomechanical analysis by a compression mode under conditions of a load of 0.01 N and a temperature rising rate of 10° C./minute continuously twice with a measurement temperature range in the first measurement of 25 to 260° C. and a measurement temperature range in the second measurement of −20 to 300° C., and the average coefficient of thermal expansion in 30 to 260° C. in the second measurement was taken as the coefficient of thermal expansion.

### (Measurement Method of Bending Elastic Modulus)

The laminate (40) and the laminate (100) were each cut into a size in the surface direction of 20 mm×50 mm and dried at 105° C. for 1 hour to produce a specimen. The specimen was used as a measurement object and the bending elastic modulus was measured using a 5t tensilon (manufactured by ORIENTEC CORPORATION, tradename “RTC-1350A”) at a room temperature (25° C.) under conditions of a crosshead speed of 1 mm/minute and a distance between fulcrums of 20 mm.

### (Measurement Method of Copper Foil Peeling Strength, and Calculation Method of Rate of Change in Copper Foil Peeling Strength According to Heat and Pressure Treatment Time)

A copper foil on one surface of the copper clad laminate produced in each example was processed by etching into a straight line form of a 3 mm width to produce a specimen. The formed straight line-shaped copper foil was mounted on a compact table-top universal tester (manufactured by Shimadzu Corporation, tradename “EZ-TEST”), and was peeled in the 90° direction at a room temperature (25° C.) to measure the copper foil peeling strength. The tensile rate in peeling the copper foil was 50 mm/minute.

The copper foil peeling strength of the copper clad laminate produced with a heat and pressure treatment time of 40 minute was taken as P (40) and the copper foil peeling strength of the copper clad laminate produced with a heat and pressure treatment time of 100 minute was taken as P (100), and the rate of change in the copper foil peeling strength according to the heat and pressure treatment time was calculated by the following formula (2).

$$Rate of change in copper foil peeling stength according to heat and pressure treatment time ( \% ) = [ P ( 100 ) - P ( 40 ) ] \times 1 \; 00 / P ( 100 ) \qquad ( 2 )$$

TABLE 1

| | | | Example | | | | | |
|---|---|---|---|---|---|---|---|---|
| | | | 1 | 2 | 3 | 4 | 5 | 6 |
| Blending | Component (A) | Maleimide resin 1 | | 18.4 | | | | |
| composition | | Maleimide resin 2 | 9.9 | | | | | |
| of resin | | Maleimide resin 3 | 9.2 | | 17.3 | | | |
| composition | | Maleimide resin 4 | | | | 17.2 | | |
| (parts by | | Maleimide resin 5 | | | | | 17.6 | |
| mass) | | Maleimide resin 6 | | | | | | 18.4 |
| | | Epoxy resin | 3.3 | 3.7 | 3.7 | 3.7 | 3.7 | 3.7 |
| | | Phenol resin | 4.7 | 5.2 | 5.2 | 5.2 | 5.2 | 5.2 |
| | Component (B) | Vinylbenzyl compound 1 | 2.7 | 2.6 | 3.8 | 3.9 | 3.5 | 2.7 |
| | | Vinylbenzyl compound 2 | | | | | | |
| | | Vinylbenzyl compound 3 | | | | | | |
| | Component (C) | Inorganic filler | 70.0 | 70.0 | 70.0 | 70.0 | 70.0 | 70.0 |
| | Component (D) | Curing accelerator | 0.075 | 0.075 | 0.075 | 0.075 | 0.075 | 0.075 |
| Physical | Heat and | Glass transition | 346 | 322 | 310 | 270 | 320 | 285 |
| properties | pressure | temperature | | | | | | |
| | treatment time: | Tg(100) (° C.) | | | | | | |
| | 100 minutes | Coefficient of thermal | 6.7 | 10.4 | 9.9 | 10.0 | 9.3 | 16.6 |
| | | expansion (ppm/° C.) | | | | | | |
| | | Bending elastic | 38 | 39 | 36 | 35 | 38 | 34 |
| | | modulus (GPa) | | | | | | |
| | | Copper foil peeling | 0.27 | 0.35 | 0.42 | 0.41 | 0.39 | 0.37 |
| | | strength P(100) | | | | | | |
| | | (kN/m) | | | | | | |
| | Heat and | Glass transition | 341 | 319 | 307 | 280 | 321 | 280 |
| | pressure | temperature | | | | | | |
| | treatment time: | Tg(100) (° C.) | | | | | | |
| | 40 minutes | Coefficient of thermal | 6.7 | 10.3 | 9.5 | 10.2 | 9.6 | 16.2 |
| | | expansion (ppm/° C.) | | | | | | |
| | | Bending elastic | 38 | 39 | 37 | 36 | 38 | 33 |
| | | modulus (GPa) | | | | | | |
| | | Copper foil peeling | 0.28 | 0.36 | 0.43 | 0.41 | 0.39 | 0.34 |
| | | strength P(40) | | | | | | |
| | | (kN/m) | | | | | | |

| | | | | | | | |
|---|---|---|---|---|---|---|---|
| | Rate of change in glass transition | 1 | 1 | 1 | −4 | 0 | 2 |
| | temperature according to heat and | | | | | | |
| | pressure treatment time (%) | | | | | | |
| Evaluation | Rate of change in copper foil peeling | −4 | −3 | −2 | 0 | 0 | 8 |
| results | strength according to heat and | | | | | | |
| | pressure treatment time (%) | | | | | | |

| | | | | | | Comparative | |
|---|---|---|---|---|---|---|---|
| | | | Example | | | Example | |
| | | | 7 | 8 | 9 | 1 | 2 |
| Blending | Component (A) | Maleimide resin 1 | 12.7 | 8.0 | 0.4 | | |
| composition | | Maleimide resin 2 | | | | 10.9 | 10.7 |
| of resin | | Maleimide resin 3 | | | | 12.1 | 11.4 |
| composition | | Maleimide resin 4 | | | | | |
| (parts by | | Maleimide resin 5 | | | | | |
| mass) | | Maleimide resin 6 | | | | | |
| | | Epoxy resin | 3.3 | 3.3 | 3.7 | 2.9 | |
| | | Phenol resin | 4.6 | 4.6 | 5.2 | 4.1 | 7.2 |
| | Component (B) | Vinylbenzyl compound 1 | | | | | 0.6 |
| | | Vinylbenzyl compound 2 | 9.4 | 14.1 | | | |
| | | Vinylbenzyl compound 3 | | | 20.6 | | |
| | Component (C) | Inorganic filler | 70.0 | 70.0 | 70.0 | 70.0 | 70.0 |
| | Component (D) | Curing accelerator | 0.075 | 0.075 | 0.075 | 0.075 | 0.075 |
| Physical | Heat and | Glass transition | 268 | 262 | 248 | 344 | 346 |
| properties | pressure | temperature | | | | | |
| | treatment time: | Tg(100) (° C.) | | | | | |
| | 100 minutes | Coefficient of thermal | 9.6 | 10.1 | 18.9 | 6.6 | 6.1 |
| | | expansion (ppm/° C.) | | | | | |
| | | Bending elastic | 33 | 33 | 30 | 38 | 39 |
| | | modulus (GPa) | | | | | |
| | | Copper foil peeling | 0.29 | 0.25 | 0.23 | 0.27 | 0.33 |
| | | strength P(100) | | | | | |
| | | (kN/m) | | | | | |
| | Heat and | Glass transition | 263 | 258 | 245 | 258 | 270 |
| | pressure | temperature | | | | | |
| | treatment time: | Tg(100) (° C.) | | | | | |
| | 40 minutes | Coefficient of thermal | 9.5 | 9.8 | 18.1 | 6.7 | 5.7 |
| | | expansion (ppm/° C.) | | | | | |
| | | Bending elastic | 34 | 33 | 30 | 33 | 38 |
| | | modulus (GPa) | | | | | |
| | | Copper foil peeling | 0.28 | 0.27 | 0.25 | 0.18 | 0.23 |
| | | strength P(40) | | | | | |
| | | (kN/m) | | | | | |

| | | | | | | |
|---|---|---|---|---|---|---|
| | Rate of change in glass transition | 2 | 2 | 1 | 25 | 22 |
| | temperature according to heat and | | | | | |
| | pressure treatment time (%) | | | | | |
| Evaluation | Rate of change in copper foil peeling | 3 | −8 | −9 | 33 | 30 |
| results | strength according to heat and | | | | | |
| | pressure treatment time (%) | | | | | |

The details of the materials in Table 1 are as follows.

### [Component (A)]

Maleimide resin 1:2,2-bis[4-(4-maleimidophenoxy)phenyl]propane
Maleimide resin 2: aminomaleimide resin obtained in Production Example 1
Maleimide resin 3: polyphenylmethane maleimide (tradename “BMI-2300”, manufactured by Daiwakasei Indsutry Co., Ltd.)
Maleimide resin 4:3,3′-dimethyl-5,5′-diethyl-4,4′-diphenylmethane bismaleimide
Maleimide resin 5: bis(4-maleimidophenyl) methane
Maleimide resin 6: biphenylaralkyl-type maleimide (“MIR-3000”, manufactured by Nippon Kayaku Co., Ltd.)
Epoxy resin: tradename “HP-9540”, manufactured by DIC Corporation
Phenol resin: tradename “Benzoxazine P-d”, manufactured by SHIKOKU CHEMICALS CORPORATION

### [Component (B)]

Vinylbenzyl compound 1: vinylbenzyl compound 1 obtained in Production Example 2
Vinylbenzyl compound 2: mixture of a compound having two vinylbenzyl groups directly bonded to an indene ring and a vinylbenzyl compound having three vinylbenzyl groups directly bonded to an indene ring (corresponding to component (B1))
Vinylbenzyl compound 3: mixture of a compound having two vinylbenzyl groups directly bonded to an indene ring and a vinylbenzyl compound having three vinylbenzyl groups directly bonded to an indene ring (corresponding to component (B1))

### [Component (C)]

Inorganic filler: spherical fused silica, average particle diameter (D₅₀): 0.5 μm

### [Component (D)]

Curing accelerator: isocyanate-masked imidazole (tradename “G-8009L”, manufactured by DKS Co. Ltd.)

It can be found from the results shown in Table 1 that the resin compositions of Examples 1 to 9 of the present embodiment have a small rate of change in the copper foil peeling strength according to the heat and pressure treatment time.

1. A resin composition comprising a thermosetting resin,
the resin composition having a rate of change in a glass transition temperature according to a heat and pressure treatment time as measured under the following conditions of −20% to +20%:
(Measurement Method of Rate of Change in Glass Transition Temperature According to Heat and Pressure Treatment Time)
seven sheets of a prepreg having a thickness of 0.1 mm and containing the resin composition and a glass cloth (type of glass: T-glass, basis weight: 114 g/m2, thickness of glass cloth: 0.098 mm) are stacked and subjected to a heat and pressure treatment under conditions of a temperature of 240° C. and a pressure of 3.0 MPa for 100 minutes or 40 minutes to obtain a laminate (100) produced with a heat and pressure treatment time of 100 minutes and a laminate (40) produced with a heat and pressure treatment time of 40 minutes;
the laminate (40) and the laminate (100) obtained are each cut into a size in a surface direction of 4 mm×30 mm and dried at 105° C. for 1 hour to produce a specimen; the specimen is used as a measurement object and is subjected to a dynamic viscoelasticity measurement using a dynamic viscoelasticity measuring device under conditions of a temperature rising rate of 5° C./minute, a frequency of 10 Hz, and a measuring temperature range of 40 to 400° C., and in a temperature-loss tangent (tan δ) curve obtained, a temperature at which tan δ is a maximum value is read as a glass transition temperature (Tg);
from a glass transition temperature Tg(100) of the laminate (100) and a glass transition temperature Tg(40) of the laminate (40), the rate of change in a glass transition temperature according to a heat and pressure treatment time is calculated by the following formula (1):
$$Rate of change in glass transition temperature according to heat and pressure treatment time ( \% ) = [ Tg ( 100 ) - Tg ( 40 ) ] \times 100 / Tg ( 100 ) . \qquad ( 1 )$$

2. The resin composition according to claim 1, wherein the glass transition temperature Tg(40) is 200 to 400° C.

3. A prepreg comprising the resin composition according to claim 1 or a semi-cured product of the resin composition.

4. A laminate comprising a cured product of the resin composition according to claim 1 and a metal foil.

5. A resin film comprising the resin composition according to claim 1 or a semi-cured product of the resin composition.

6. A printed wiring board comprising a cured product of the resin composition according to claim 1.

7. A semiconductor package comprising the printed wiring board according to claim 6 and a semiconductor element.

8. A semiconductor package comprising a semiconductor element and a cured product of the resin composition according to claim 1, the cured product of the resin composition sealing the semiconductor element.

9. A prepreg comprising a resin composition and a fiber base material, the resin composition containing a thermosetting resin, the prepreg having a rate of change in a glass transition temperature according to a heat and pressure treatment time as measured under the following conditions of −20% to +20%:
(Measurement method of rate of change in glass transition temperature according to heat and pressure treatment time)
two or more sheets of the prepreg are stacked and subjected to a heat and pressure treatment under conditions of a temperature of 240° C. and a pressure of 3.0 MPa for 100 minutes or 40 minutes to obtain a laminate (100′) produced with a heat and pressure treatment time of 100 minutes and a laminate (40′) produced with a heat and pressure treatment time of 40 minutes;
the laminate (40′) and the laminate (100′) obtained are each cut into a size in a surface direction of 4 mm×30 mm and dried at 105° C. for 1 hour to produce a specimen; the specimen is used as a measurement object and is subjected to a dynamic viscoelasticity measurement using a dynamic viscoelasticity measuring device under conditions of a temperature rising rate of 5° C./minute, a frequency of 10 Hz, and a measuring temperature range of 40 to 400° C., and in a temperature-loss tangent (tan δ) curve obtained, a temperature at which tan δ is a maximum value is read as a glass transition temperature (Tg);
from a glass transition temperature Tg(100′) of the laminate (100′) and a glass transition temperature Tg(40′) of the laminate (40′), the rate of change in a glass transition temperature according to a heat and pressure treatment time is calculated by the following formula (1′):
$$Rate of change in glass transition temperature according to heat and pressure treatment time ( \% ) = [ Tg ( {100}^{′} ) - Tg ( {40}^{′} ) ] \times 100 / Tg ( {100}^{′} ) \qquad ( {1}^{′} )$$
